(19) United States
(12) Patent Application Publication
(10) Pub. No.: US 2023/0361168 A1
(43) Pub. Date: Nov. 9, 2023

(54) SEMICONDUCTOR DEVICE

(71) Applicant: Power Master Semiconductor Co., Ltd., Cheongju-si (KR)

(72) Inventors: Sangtae HAN, Incheon (KR); Minjae Park, Bucheon-si (KR)

(21) Appl. No.: 18/224,110

(22) Filed: Jul. 20, 2023

Related U.S. Application Data
(63) Continuation-in-part of application No. 16/716,832, filed on Dec. 17, 2019, now abandoned.

(30) Foreign Application Priority Data
Aug. 30, 2019 (KR) 10-2019-0107447

(51) Int. Cl. H01L 29/06; H01L 29/10; H01L 29/78

(52) U.S. Cl. CPC H01L 29/0615; H01L 29/1095; H01L 29/7802

(57) ABSTRACT

A semiconductor device is provided. The semiconductor device includes: a first semiconductor layer having an N-type of conductivity; and a second semiconductor layer that is formed on the first semiconductor layer, and including an active region, a frame region, and a termination region, wherein the active region includes a plurality of first P-pillars and first N-pillars formed between the plurality of first P-pillars, the frame region includes an upper frame region formed to extend in a first direction while having a P-type of conductivity, and a lower frame region that is formed below the upper frame region and including a plurality of second P-pillars and second N-pillars formed between the plurality of second P-pillars, and the termination region includes an upper termination region that extends in the first direction while having the P-type of conductivity, a middle termination region having the N-type of conductivity and formed below the upper termination region, and a lower termination region formed below the middle termination region and including a plurality of third P-pillars and third N-pillars formed between the plurality of third P-pillars.

### CROSS-REFERENCE TO RELATED APPLICATION

This application is a Continuation in part application of U.S. patent application Ser. No. 16/716,832 filed on Dec. 17, 2019, which claims priority to and the benefit of Korean Patent Application No. 10-2019-0107447 filed in the Korean Intellectual Property Office on Aug. 30, 2019, the entire contents of which are incorporated herein by reference.

### BACKGROUND

### (a) Technical Field

The present disclosure relates to a semiconductor device.

### (b) Description of the Related Art

A power-type metal oxide semiconductor field effect transistor (MOSFET) may be used as a switch, and requires low on-resistance, a high breakdown voltage, and high switching speed. In particular, a super-junction MOSFET, which is a representative example of a high voltage resistance MOSFET, is a kind of Si-MOSFET, and has a high speed switching operation at relatively low power compared to an insulated gate bipolar transistor (IGBT) and a SiC-MOSFET.

By improving the fact that when the breakdown voltage is increased, a drift layer is thickened and thus on-resistance is increased in a planar MOSFET, the super-junction MOSFET alternately disposes a plurality of vertical PN junctions to reduce on-resistance, and a reduction of the amount of gate charge required to charge the input capacitance, which is the sum of the gate-source capacitance and the gate-drain capacitance, can be realized.

However, charge imbalance resulting from pillar structures that are alternately disposed to the drift layer of a super-junction MOSFET (hereinafter referred to as a super-junction semiconductor device) may result in poor breakdown characteristics and damage to the device, and accordingly, a design for a structure that can balance changes is required.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a semiconductor device that can solve a charge imbalance problem in a super-junction semiconductor device and assure reliability.

A semiconductor device according to an exemplary embodiment of the present disclosure includes: a first semiconductor layer having an N-type of conductivity; and a second semiconductor layer that is formed on the first semiconductor layer, and including an active region, a frame region, and a termination region, wherein the active region includes a plurality of first P-pillars and first N-pillars formed between the plurality of first P-pillars, the frame region includes an upper frame region formed to extend in a first direction while having a P-type of conductivity, and a lower frame region that is formed below the upper frame region and including a plurality of second P-pillars and second N-pillars formed between the plurality of second P-pillars, and the termination region includes an upper termination region that extends in the first direction while having the P-type of conductivity, a middle termination region having the N-type of conductivity and formed below the upper termination region, and a lower termination region formed below the middle termination region and including a plurality of third P-pillars and third N-pillars formed between the plurality of third P-pillars, wherein the upper termination region may include a plurality of segmentation area logically defined to distinguish areas having different impurity concentrations in the upper termination region, the plurality of segmentation area having a first segmentation area, a second segmentation area, and a third segmentation area, and wherein the impurity concentration of the first segmentation area may be the highest, the impurity concentration of the second segmentation area may be lower than that of the first segmentation area, and the impurity concentration of the n-th segmentation area may be the lowest.

In some exemplary embodiments of the present disclosure, the entire lower termination region may be covered by the upper termination region.

In some exemplary embodiments of the present disclosure, the middle termination region and the upper termination region may be sequentially formed on the third P-pillar.

In some exemplary embodiments of the present disclosure, the second P-pillar may be connected to the top surface of the second semiconductor layer through the upper frame region.

In some exemplary embodiments of the present disclosure, the third P-pillar may be distanced from the top surface of the second semiconductor layer

In some exemplary embodiments of the present disclosure, the top surface of the middle termination region may be distanced from the top surface of the second semiconductor layer.

In some exemplary embodiments of the present disclosure, the middle termination region may be connected with at least one of the plurality of third N-pillars of the lower termination region.

In some exemplary embodiments of the present disclosure, the upper termination region may be connected with the upper frame region.

In some exemplary embodiments of the present disclosure, the upper frame region may be connected with at least one of the plurality of second P-pillars of the lower frame region.

In some exemplary embodiments of the present disclosure, impurity concentration of the upper frame region may be higher than that of the upper termination region.

### BRIEF DESCRIPTION OF THE DRAWINGS

FIG. 1 is a top plan view provided for description of a semiconductor device according to an exemplary embodiment of the present disclosure.

FIG. 2A is a cross-sectional view of one direction for description of a semiconductor device according to an exemplary embodiment of the present disclosure.

FIG. 2B to FIG. 2D are cross-sectional views of the semiconductor device of FIG. 2A in different directions.

FIG. 3 is a cross-sectional view of a semiconductor device according to another exemplary embodiment of the present disclosure, provided for description of the semiconductor device in one direction.

FIG. 4 to FIG. 6 are provided for description of an example of a mask layer for manufacturing a semiconductor device according to an exemplary embodiment of the present disclosure.

FIG. 7 and FIG. 8 are provided for description of an example of a mask layer for manufacturing a semiconductor device according to an exemplary embodiment of the present disclosure.

FIG. 9 to FIG. 15 are provided for description of an example of a method for manufacturing a semiconductor device by using the mask layer of FIG. 7.

FIG. 16 is provided for description of another example of a mask layer for manufacturing a semiconductor device according to the exemplary embodiment of the present disclosure.

FIG. 17 is provided for description of another example of a mask layer for manufacturing a semiconductor device according to the exemplary embodiment of the present disclosure.

FIG. 18 is provided for description of another example of a mask layer for manufacturing a semiconductor device according to the exemplary embodiment of the present disclosure.

FIG. 19 is a cross-sectional view provided for description of a semiconductor device according to an exemplary embodiment of the present disclosure.

FIG. 20 is a cross-sectional view provided for description of a semiconductor device according to another exemplary embodiment of the present disclosure.

FIG. 21 is a cross-sectional view provided for description of a manufacturing step of a semiconductor device according to another exemplary embodiment of the present disclosure.

FIG. 22 and FIG. 23 are provided for description of advantageous effects of the semiconductor devices according to the exemplary embodiments of the present disclosure.

FIG. 24 is a cross-sectional view of one direction for description of a semiconductor device according to an exemplary embodiment of the present disclosure.

FIG. 25 illustrates a profile of a surface electric field along line AA′ of the semiconductor device of FIG. 24.

FIG. 26 is provided for description of another example of a mask layer for manufacturing the semiconductor device of FIG. 24.

FIG. 27 is a cross-sectional view of one direction for description of a semiconductor device according to an exemplary embodiment of the present disclosure.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

In addition, unless explicitly described to the contrary, the word “comprise” and variations such as “comprises” or “comprising” will be understood to imply the inclusion of stated elements but not the exclusion of any other elements.

Although exemplary embodiments of the present disclosure are mainly described with an example of a super-junction semiconductor device, the technical spirit of the present disclosure is not limited thereto, and the present disclosure can be applied to other types of power switch technologies including IGBT devices, Schottky rectifiers, various types of bipolar switches, and various types of thyristors and rectifiers. In addition, although exemplary embodiments of the present disclosure are described using a specific P region and N region, the technical spirit of the present disclosure is not limited thereto, and the technical spirit of the present disclosure may also be applied to a semiconductor device an opposite conductivity type in the corresponding region. Hereinafter, the term, “semiconductor device” refers to a super-junction MOSFET and a super-junction semiconductor device, except where specifically noted.

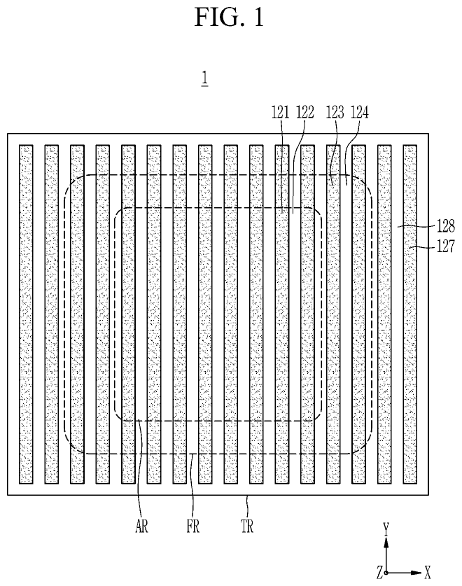

FIG. 1 is a top plan view provided for description of a semiconductor device according to an exemplary embodiment of the present disclosure.

Referring to FIG. 1, a semiconductor device 1 according to an exemplary embodiment of the present disclosure may include an active region AR, a frame region FR, and a termination region TR.

The active region AR may include first P-pillars 121 and first N-pillars 122 alternately arranged along a first direction X. That is, the active region AR may include a plurality of first P-pillars 121 and first N-pillars 122 formed between the plurality of first P-pillars 121.

The termination region TR may include third P-pillars 127 and third N-pillars 128 alternately arranged along the first direction X. That is, the termination region TR may include a plurality of third P-pillars 127 and third N-pillars 128 formed between the plurality of third P-pillars 127.

The frame region FR may correspond to a transition region disposed between the active region AR and the termination region TR. The frame region FR may include second P-pillars 123 and second N-pillars 124 alternately arranged along the first direction X. That is, the frame region FR may include a plurality of second P-pillars 123 and second N-pillars 124 formed between the plurality of second P-pillars 123.

In the present exemplary embodiment, the frame region FR is formed to surround the active region A and the termination region TR is formed to surround the frame region FR, but the range of the present disclosure is not limited thereto.

Such a layout of the first P-pillars 121 and the first N-pillars 122 of the active region AR, a layout of the second P-pillars 123 and the second N-pillars 124 of the frame region FR, and a layout of the third P-pillars 127 and the third N-pillars 128 of the termination region TR are not limited to the layouts shown in FIG. 1, and it can be understood that various modifications may be made according to specific implementation purposes, and accordingly, characteristics of the semiconductor device 1 may vary.

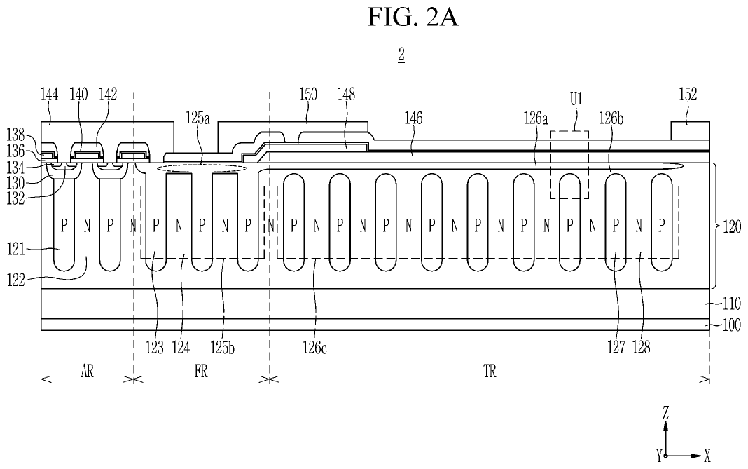

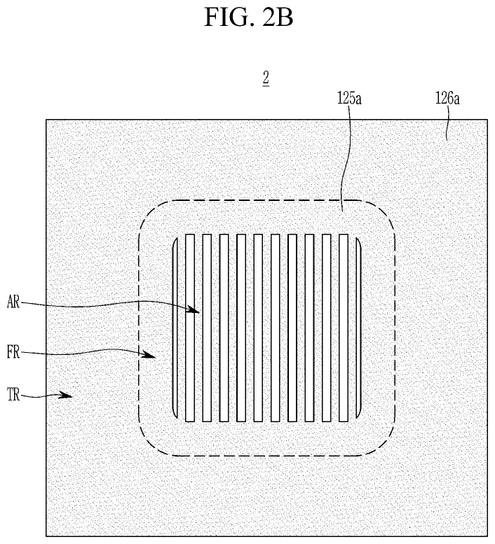

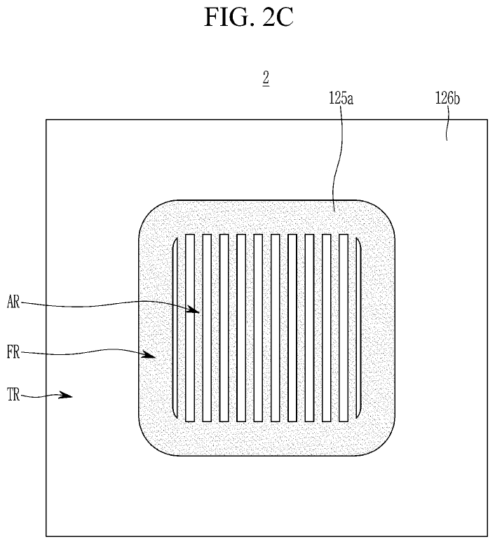

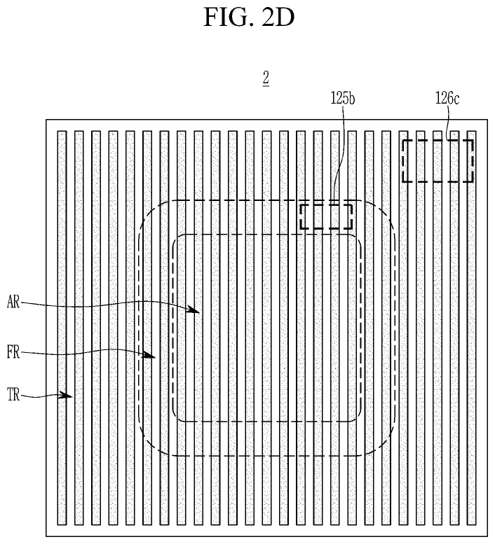

FIG. 2A is a cross-sectional view of one direction for description of a semiconductor device according to an exemplary embodiment of the present disclosure.

Referring to FIG. 2A, a semiconductor device 2 according to an exemplary embodiment of the present disclosure may include a first semiconductor layer 110 and a second semiconductor layer 120. The active region AR, the frame region FR, and the termination region TR, which have been described above with reference to FIG. 1, may respectively include first semiconductor layers 110 and the second semiconductor layers 120.

The first semiconductor layer 110 is formed on a drain wiring layer 100, and may be divided into the active region AR, the frame region FR, and the termination region TR, which have been described above with reference to FIG. 1.

The first semiconductor layer 110 may have an N-type of conductivity. For example, the first semiconductor layer 110 may be a part of a semiconductor substrate that is heavily doped with an N-type impurity. Alternatively, although not shown, the first semiconductor layer 110 may refer to a semiconductor substrate that is heavily doped with N-type impurities and an epitaxial layer heavily doped with N-type impurities formed on the semiconductor substrate.

The second semiconductor layer 120 may be divided into the active region AR, the frame region FR, and the termination region TR, which have been described above with reference to FIG. 1.

A portion of the second semiconductor layer 120, corresponding to the active region AR may correspond to a drift layer. That is, the active region AR of the second semiconductor layer 120 may have a super-junction structure in which first P-pillars 121 including P-type impurities and first N-pillars 122 including N-type impurities are alternately arranged along a first direction X that is parallel with the top surface of the first semiconductor layer 110. That is, the active region AR of the second semiconductor layer 120 may include a plurality of first P-pillars 121 and first N-pillars 122 formed between the plurality of first P-pillars 121.

The first P-pillars 121 and the first N-pillars 122 may extend in a second direction Y that is perpendicular to the first direction X, while having a predetermined width in the first direction X.

In some exemplary embodiments of the present disclosure, concentration of the P-type impurity of the first P-pillar 121 may be the same as that of the N-type impurity of the first N-pillar 122. In addition, the width of the first P-pillar 121 in the first direction X may be the same as that of the first N-pillar 122 in the first direction X. In some exemplary embodiments of the present disclosure, the P-type impurity concentration of the first P-pillar 121 may be higher than the N-type impurity concentration of the first N-pillar 122, and the width of the P-pillar 121 in the first direction X may be narrower than the width of the first N-pillar 122 in the first direction X. Alternatively, in some exemplary embodiments of the present disclosure, the P-type impurity concentration of the first P-pillar 121 may be lower than the N-type impurity concentration of the first N-pillar 122, and the width of the P-pillar 121 in the first direction X may be wider than the width of the first N-pillar 122 in the first direction X. In any case, the impurity concentration and width may be appropriately adjusted so that the P-type charge amount and the N-type charge amount of the active region AR of the second semiconductor layer 120 can be balanced.

A P body region 130 may be formed on the first P-pillar 121, and a P+ region 132 may be formed in the P body region 120. Two N+ regions 134 that are distanced from each other while having a predetermined depth from the top surface of the second semiconductor layer 120 may be formed in the P+ region 132.

A gate dielectric layer 136 may be formed on the first N-pillar 122, and an active poly gate 138 may be formed on the gate dielectric layer 136. A spacer 140 may be conformally formed on the active poly gate 138, and the spacer 140 may include, for example, a silicon nitride. An insulation layer 142 may be formed on the spacer 140. A source electrode 144 may be formed on the insulation layer 142, and the source electrode 144 may be electrically connected with the P+ region 132 by contacting the same.

A structure formed on the first P-pillar 121 and the first N-pillar 122 may not be limited to the above-described structure, and may be modified depending on specific implement purposes.

As described above with reference to FIG. 1, the frame region FR of the second semiconductor layer 120 may be formed to surround the active region AR of the second semiconductor layer 120

The frame region FR of the second semiconductor layer 120 may include second P-pillars 123 and second N-pillars 124 that are alternately arranged along the first direction X that is parallel with the top surface of the first semiconductor layer 110. That is, the frame region FR of the second semiconductor layer 120 may include a plurality of second P-pillars 123 and second N-pillars 124 formed between the plurality of second P-pillars 123.

Specifically, the frame region FR of the second semiconductor layer 120 may include an upper frame region 125a and a lower frame region 125b.

The upper frame region 125a has a P-type of conductivity, and may extend in the first direction X that is parallel with the top surface of the first semiconductor layer 110.

The lower frame region 125b is formed below the upper frame region 125a, and may include a plurality of second P-pillars 123 and second N-pillars 124 formed between the plurality of second P-pillars 123.

In some exemplary embodiments of the present disclosure, the width of the second P-pillar 123 and the second N-pillar 124 in the first direction X and the impurity concentration of the second P-pillar 123 and the second N-pillar 124 may be the same as the width of the first direction of the first P-pillar 121 and the first N-pillar 122 of the active region AR in the first direction X and the impurity concentration of the first P-pillar 121 and the first N-pillar 122. Alternatively, the width of the second P-pillar 123 and the second N-pillar 124 in the first direction X and the impurity concentration of the second P-pillar 123 and the second N-pillar 124 may be different from the width of the first direction of the first P-pillar 121 and the first N-pillar 122 of the active region AR in the first direction X and the impurity concentration of the first P-pillar 121 and the first N-pillar 122, and the impurity concentration and width may be appropriately adjusted so that the balance between the P-type charge amount and the N-type charge amount included in the frame region FR may be maintained,

A spacer 140 and an insulation layer 142 may be disposed on the upper frame region 125a. At least a part of the insulation layer 142 may correspond to a region where the source electrode 144 and a gate electrode 150 are not formed. That is, the source electrode 144 and the gate electrode 150 may be formed apart from each other. In addition, a region that contacts the source electrode 144 and thus forms an electrical connection with the source electrode 144 may exist on the upper frame region 125a.

A structure formed on the upper frame region 125a may be variously modified depending on detailed implementation purposes rather than being limited to the above-stated structure. For example, a field oxide layer 146 may be additionally formed before the insulation layer 142 is formed, or the spacer 140 may be formed with a shape that is different from the shape shown in FIG. 2A.

In the present exemplary embodiment, the second P-pillar 123 may be connected to the top surface of the second semiconductor layer 120 through the upper frame region 125a. Accordingly, a plurality of second P-pillars 123 may contact the source electrode 144 through the upper surface of the second semiconductor layer 120 to form an electrical connection.

Meanwhile, in the present exemplary embodiment, the upper frame region 125a may be connected to at least one of the plurality of second P-pillars 123 of the lower frame region 125b. Accordingly, the plurality of second P-pillars 123 may be electrically connected to each other through the upper frame region 125a. For example, three second P-pillars 123 are connected with the upper frame region 125a and thus they may have the shape as shown in 2A, but the number and specific shape of the second P-pillars 123 may vary rather than being limited to the number and specific shape shown in FIG. 2A.

As previously described with reference to FIG. 1, the termination region TR of the second semiconductor layer 120 may be formed to surround the frame region FR of the second semiconductor layer 120.

The termination region TR of the second semiconductor layer 120 may include third P-pillars 127 and third N-pillars 128 that are alternately arranged along the first direction X that is parallel with the top surface of the first semiconductor layer 110. That is, the termination region TR of the second semiconductor layer 120 may include a plurality of third P-pillars 127 and a plurality of third N-pillars 128 formed between the plurality of third P-pillars 127.

Specifically, the termination region TR of the second semiconductor layer 120 may include an upper termination region 126a, a middle termination region 126b, and a lower termination region 126c.

The upper termination region 126a may have a P-type of conductivity, and may extend in the first direction X that is parallel with the top surface of the first semiconductor layer 110.

The middle termination region 126b may have an N-type of conductivity, and may be formed below the upper termination region 126a.

The lower termination region 126c is formed below the middle termination region 126b, and may include a plurality of third P-pillars 127 and a plurality of third N-pillars 128 formed between the plurality of third P-pillars 127. The lower termination region 126c has a super-junction structure in which the third P-pillars 127 including a P-type of impurity and the third N-pillars 128 including an N-type of impurity are alternately arranged along the first direction X that is parallel with the top surface of the first semiconductor layer 110 such that a breakdown voltage of the semiconductor device 2 can be increased.

In some exemplary embodiments of the present disclosure, the width of the third P-pillar 127 and the third N-pillar 128 in the first direction X and the impurity concentration thereof may be the same as the width of the first P-pillar 121 and the first N-pillar 122 in the first direction X of the active region AR and the impurity concentration thereof. Alternatively, the first direction (X) width and the impurity concentration of the third P-pillar 127 and the third N-pillar 128 may be different from the first direction (X) width and the impurity concentration of the first P-pillar 121 and the first N-pillar 122 of the active region AR, and the impurity concentration and width may be appropriately selected so that the P-type charge amount and the N-type charge amount included in the termination region TR can be balanced.

The field oxide layer 146 may be formed on the upper termination region 126a, and the spacer 140 and the insulation layer 142 may be formed on the field oxide layer 146. In particular, in some area on the upper termination region 126a, a field plate 148 may be formed on the field oxide layer 146, and the spacer 140 and the insulation layer 142 may be formed on the field plate 148. A gate electrode 150 may be formed on the insulation layer 142, and the gate electrode 150 may be electrically connected with the field plate 148 by contacting the same.

In some exemplary embodiments of the present disclosure, the field plate 148 may extend to the frame area FR so as to form an electrical connection with the upper frame region 125a, but the range of the present disclosure is not limited thereto.

Meanwhile, a floating electrode 152 may be formed at a distance from the gate electrode 150 on the field oxide layer 146. The floating electrode 152 is located at the end of the termination region TR, and can serve as a field stop layer to stop the electric field. Although the floating electrode 150 is referred to as a floating electrode 150 in the sense that it is not connected with an outer terminal of a chip included in the semiconductor device 2, it does not mean that the floating electrode 150 is electrically floating. For example, the silicon (Si) region formed in some areas of the chip of the floating electrode 150 may be electrically contacted.

The structure formed on the upper termination region 126a is not limited to the above-described structure, and may be modified as much as the specific implementation purpose.

In the present exemplary embodiment, the upper termination region 126a may be connected with the upper frame region 125a of the frame region FR. Accordingly, the upper termination region 126a may be electrically connected with the plurality of second P-pillars 123 of the frame region FR, and may form an electrical connection with the source electrode 144 by contacting the source electrode 144 through the top surface of the semiconductor layer 120.

In the present exemplary embodiment, an impurity concentration of the upper frame region 125a of the frame region FR may be higher than that of the upper termination region 126a. That is, both the upper frame region 125a and the upper termination region 126a of the frame region FR are doped with a P-type impurity, but the upper frame region 125a of the frame region FR may be more heavily doped with the P-type impurity. However, the range of the present disclosure is not limited thereto.

Meanwhile, in the present exemplary embodiment, the top surface of the middle termination region 126b may be distanced from the top surface of the second semiconductor layer 120. That is, the top surface of the middle termination region 126b may be distanced from the bottom surface of the field oxide layer 146. In addition, the bottom surface of the upper termination region 126a and the top surface of the middle termination region 126b may form a PN junction.

In the present exemplary embodiment, the middle termination region 126b may be connected with at least one of the plurality of third N-pillars 128 of the lower termination region 126c. Accordingly, the plurality of third N-pillars 128 may be electrically connected with each other through the middle termination region 126b.

Meanwhile, in the present exemplary embodiment, the entire lower termination region 126c may be covered by the upper termination region 126a. That is, the upper termination region 126a may be formed to wholly cover the top surface of the termination region TR.

Referring to a region U1, in the present exemplary embodiment, the middle termination region 126b and the upper termination region 126a may be sequentially formed on the third P-pillar 127. In addition, the third P-pillar 127 may be formed to be distanced from the top surface of the second semiconductor layer 120.

FIG. 2B to FIG. 2D are cross-sectional views of the semiconductor device of FIG. 2A in different directions.

Specifically, FIG. 2B is a cross-sectional view of the semiconductor device of FIG. 2A, taken along a virtual line that penetrates the upper termination region 126a in a first direction X, that is, a cross-section viewed from a third direction Z that is perpendicular to the first direction X and the second direction Y.

Referring to FIG. 2B, P body regions 130 and surface N regions formed between the P body regions 130 are alternately arranged in the active region AR. Here, as previously described with reference to FIG. 2A, the P body region 130 may include a P+ region 132 and an N+ region 134. In addition, the upper frame region 125a is disposed in the frame region FR, and the upper terminal region 126a is disposed in the termination region TR. That is, the upper termination region 126a in the termination region TR may wholly cover the termination region TR, and for example, may cover the plurality of third P pillars 127 of the lower termination region 126c.

FIG. 2C is a cross-sectional view of the semiconductor device of FIG. 2A, taken along a virtual line that penetrates the middle termination region 126b in the first direction X, that is, a cross-section viewed from the third direction Z.

Referring to FIG. 2C, P body regions 130 and the surface N regions formed between the P body regions 130 are alternately arranged in the active region AR. In addition, the upper frame region 125a is disposed in the frame region FR, and the middle terminal region 126b is disposed in the termination region TR.

FIG. 2D is a cross-sectional view of the semiconductor device of FIG. 2A, taken along a virtual line that penetrates the lower termination region 126c in the first direction X, that is, viewed from the third direction Z.

Referring to FIG. 2D, the first P-pillar 121 and the first N-pillar 122 are alternately arranged in the active region AR. In addition, the lower frame region 125b is formed in the frame region FR and thus the second P-pillar 123 and the second N-pillar 124 are alternately arranged, and the lower termination region 126c is formed in the termination region TR and thus the third P-pillar 127 and the third N-pillar 128 are disposed.

According to the present exemplary embodiment described with reference to FIG. 2A to FIG. 2D, a charge imbalance problem in which the balance between the P-type charge amount and the N-type charge amount is broken in a corner portion of the termination region of the semiconductor device 2 can be solved. In addition, the expansion speed of the depletion region can be adjusted to be uniform in all directions of the termination region surface to prevent damage caused by high electric fields, and to reduce an electric field level applied to the surface of the termination region and facilitate profile adjustment, thereby assuring reliability and improving performance of the semiconductor device 2.

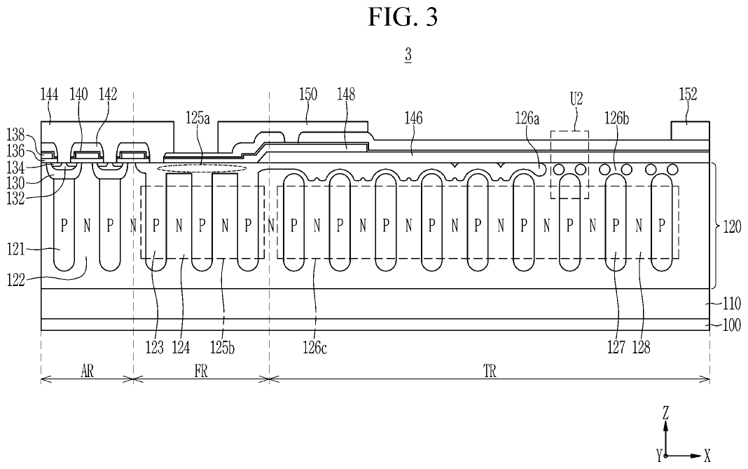

FIG. 3 is a cross-sectional view of a semiconductor device according to another exemplary embodiment of the present disclosure, provided for description of the semiconductor device in one direction.

Referring to FIG. 3, a semiconductor device 3 according to another exemplary embodiment of the present disclosure may include a first semiconductor layer 110 and a second semiconductor layer 120, each having a similar structure as described with reference to FIG. 2A.

The first semiconductor layer 110 is formed on a drain wiring layer 100, and may be divided into an active region AR, a frame region FR, and a termination region TR, which are described above with reference to FIG. 1.

The second semiconductor layer 120 is formed on the first semiconductor layer 110, and may be divided into an active region AR, a frame region FR, and a termination region TR, which are described above with reference to FIG. 1.

The active region AR of the second semiconductor layer 120 may have a super-junction structure in which first P-pillars 121 including P-type impurities and first N-pillars 122 including N-type impurities are alternately arranged along a first direction X that is parallel with the top surface of the first semiconductor layer 110. That is, the active region AR of the second semiconductor layer 120 may include a plurality of first P-pillars 121 and first N-pillars 122 formed between the plurality of first P-pillars 121.

A P body region 130 is formed on the first P-pillar 121, and a P+ region 132 may be formed in the P body region 130. Two N+ regions 134 that are distanced from each other while having a predetermined depth from the top surface of the second semiconductor layer 120 may be formed in the P+ region 132.

A gate dielectric layer 136 is formed on the first N-pillar 122, and an active poly gate 138 may be formed on the gate dielectric layer 136. A spacer 140 may be conformally formed on the active poly gate 138, and the spacer 140 may include, for example, a silicon nitride. An insulation layer 142 may be formed on the spacer 140. A source electrode 144 may be formed on the insulation layer 142, and the source electrode 144 may be electrically connected with the P+ region 132 by contacting the same.

A structure formed on the first P-pillar 121 and the first N-pillar 122 may not be limited to the above-described structure, and may be modified depending on specific implement purposes.

The frame region FR of the second semiconductor layer 120 may include an upper frame region 125a and a lower frame region 125b. The upper frame region 125a has a P-type of conductivity, and may extend in the first direction X that is parallel with the top surface of the first semiconductor layer 110. The lower frame region 125b is formed below the upper frame region 125a, and may include a plurality of second P-pillars 123 and second N-pillars 124 formed between the plurality of second P-pillars 123.

A spacer 140 and an insulation layer 142 may be formed on the upper frame region 125a. At least a part of the insulation layer 142 may correspond to a region where the source electrode 144 and the gate electrode 150 are not formed. That is, the source electrode 144 and the gate electrode 150 may be formed apart from each other. In addition, a region that contacts the source electrode 144 and thus forms an electrical connection with the source electrode 144 may exist on the upper frame region 125a.

A structure formed on the upper frame region 125a may be variously modified depending on detailed implementation purposes rather than being limited to the above-stated structure. For example, a field oxide layer 146 may be additionally formed before the insulation layer 142 is formed, or the spacer 140 may be formed with a shape that is different from the shape shown in FIG. 3.

In the present exemplary embodiment, the second P-pillar 123 may be connected to the top surface of the second semiconductor layer 120 through the upper frame region 125a. Accordingly, a plurality of second P-pillars 123 may contact the source electrode 144 through the upper surface of the second semiconductor layer 120 to form an electrical connection.

Meanwhile, in the present exemplary embodiment, the upper frame region 125a may be connected to at least one of the plurality of second P-pillars 123 of the lower frame region 125b. Accordingly, the plurality of second P-pillars 123 may be electrically connected to each other through the upper frame region 125a. For example, three second P-pillars 123 are connected with the upper frame region 125a, and thus may have a shape as shown in FIG. 2A, but the number and specific shape of the second P-pillar 123 are not limited to FIG. 2A and may vary.

The termination region TR of the second semiconductor layer 120 may include an upper termination region 126a, a middle termination region 126b, and a lower termination region 126c. The upper termination region 126a has a P-type of conductivity and may extend in a first direction X parallel to the top surface of the first semiconductor layer 110. The middle termination region 126b may have an N-type of conductivity, and may be formed below the upper termination region 126a. The lower termination region 126c is formed below the middle termination region 126b, and may include a plurality of third P-pillars 127 and a plurality of a plurality of third N-pillars 128 formed between the plurality of third P-pillars 127. The lower termination region 126c has a super-junction structure in which the third P-pillars 127 including a P-type of impurity and the third N-pillars 128 including an N-type of impurity are alternately arranged along the first direction X that is parallel with the top surface of the first semiconductor layer 110 such that a breakdown voltage of the semiconductor device 2 can be increased.

A field oxide layer 146 may be formed on the upper termination region 126a, and a spacer 140 and an insulation layer 142 may be formed on the field oxide layer 146. In particular, in some area on the upper termination region 126a, a field plate 148 may be formed on the field oxide layer 146, and the spacer 140 and the insulation layer 142 may be formed on the field plate 148. A gate electrode 150 may be formed on the insulation layer 142, and the gate electrode 150 may be electrically connected with the field plate 148 by contacting the same.

In some exemplary embodiments of the present disclosure, the field plate 148 may extend to the frame area FR so as to form an electrical connection with the upper frame region 125a, but the range of the present disclosure is not limited thereto.

Meanwhile, a floating electrode 152 may be formed at a distance from the gate electrode 150 on the field oxide layer 146. The floating electrode 152 is located at the end of the termination region TR and can serve as a field stop layer to stop the electric field. Although the floating electrode 150 is referred to as a floating electrode 150 in the sense that it is not connected with an outer terminal of a chip including the semiconductor device 2, it does not mean that the floating electrode 150 is electrically floating. For example, the silicon (Si) region formed in some areas of the chip of the floating electrode 150 may be electrically contacted.

The structure formed on the upper termination region 126a is not limited to the above-described structure, and may be modified as much as the specific implementation purpose.

In the present exemplary embodiment, the upper termination region 126a may be connected with the upper frame region 125a of the frame region FR. Accordingly, the upper termination region 126a may be electrically connected with the plurality of second P-pillars 123 of the frame region FR, and may form an electrical connection with the source electrode 144 by contacting the source electrode 144 through the top surface of the semiconductor layer 120.

In the present exemplary embodiment, an impurity concentration of the upper frame region 125a of the frame region FR may be higher than that of the upper termination region 126a. That is, both the upper frame region 125a and the upper termination region 126a of the frame region FR are doped with a P-type impurity, but the upper frame region 125a of the frame region FR may be more heavily doped with the P-type impurity. However, the range of the present disclosure is not limited thereto.

In the present exemplary embodiment, the middle termination region 126b may be connected with at least one of the plurality of third N-pillars 128 of the lower termination region 126c. Accordingly, the plurality of third N-pillars 128 may be electrically connected with each other through the middle termination region 126b.

In particular, in the present exemplary embodiment, at least a part of the lower termination region 126c is covered by the upper termination region 126a, and at least another part of the lower termination region 126c may not be covered by the upper termination region 126a. That is, unlike the semiconductor device 2 of FIG. 2, in which the upper termination region 126a wholly covers the top surface of the termination region TR, the upper termination region 126a of the semiconductor device 3 may partially cover the top surface of the termination region TR.

Accordingly, in the present exemplary embodiment, a part of the middle termination region 126b may extend to a height where the upper termination region 126a is formed.

In addition, accordingly, in the present exemplary embodiment, at least a part of the middle termination region 126b contacts the top surface of the second semiconductor layer 120, and at least another part of the top surface of the middle termination region 126b may be distanced from the top surface of the second semiconductor layer 120.

Further, accordingly, referring to a region U2, in the present exemplary embodiment, a part of the upper terminal region 126a and a part of the middle termination region 126b may be formed on the third P-pillar 127.

According to the present exemplary embodiment, a charge imbalance problem in which balances between P-type charges and N-type charges in a corner portion of the termination region of the semiconductor device 3 can be solved. In addition, the expansion speed of the depletion region can be adjusted to be uniform in all directions of the termination region surface to prevent damage caused by high electric fields, and to reduce an electric field level applied to the surface of the termination region and facilitate profile adjustment, thereby assuring reliability and improving performance of the semiconductor device 3.

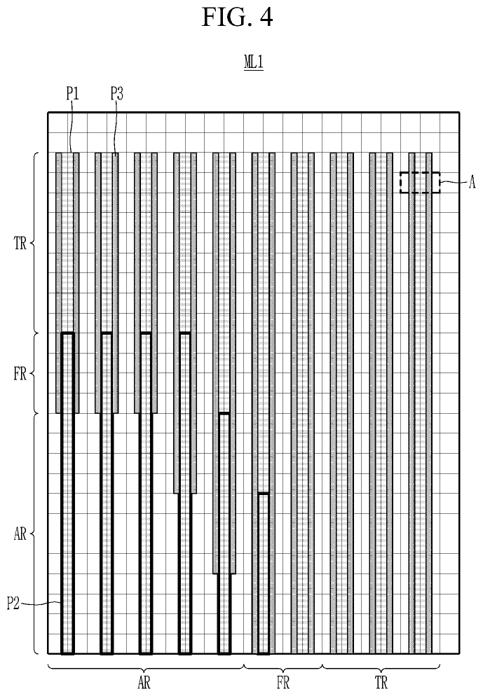

FIG. 4 to FIG. 6 are provided for description of an example of a mask layer for manufacturing a semiconductor device according to an exemplary embodiment of the present disclosure.

Referring to FIG. 4, a mask layer ML1 for manufacturing a semiconductor device according to an exemplary embodiment of the present disclosure may include an active region AR, a frame region FR, and a termination region TR.

The mask layer ML1 may include a first pillar mask pattern P1, a second pillar mask pattern P2, and a third pillar mask pattern P3.

The first pillar mask pattern P1 may be a pattern used for implantation of a P-type impurity into an epitaxial layer to form a first P-pillar 121 formed in the active region AR, a second P-pillar 123 formed in the frame region FR, and a third P-pillar 127 formed in the termination region TR.

The second pillar mask pattern P2 may be a pattern used for implantation of a P-type impurity into the epitaxial layer for forming the first P pillar formed in the active region AR, the second P-pillar 123 formed in the frame region FR.

The third pillar mask pattern P3 may be a pattern used for implantation of a P-type impurity into the epitaxial layer to form an upper frame region 125a connected with the second P-pillar 123 formed in the frame region FR, and an upper terminal region 126a formed in the terminal region TR so as to be connected with the upper frame region 125a.

In some exemplary embodiments of the present disclosure, the upper frame region may be further ion implanted after ion implantation using the third pillar mask pattern P3 according to a specific implementation purpose. For example, after forming and etching the field oxide layer 146, high concentration ion implantation may be further performed on the upper frame region 125a.

In the present exemplary embodiment, in the mask layer ML1, the pattern of the third pillar mask pattern P3 may extend in one direction, similar to the first pillar mask pattern P1.

In this case, the pitch of the third pillar mask pattern P3 of the surface of the termination region TR may be formed to be smaller than the pitch of the first pillar mask pattern P1. For example, the pitch of the third pillar mask pattern P3 of the surface of the termination region TR may be formed to be half the pitch of the first pillar mask pattern P1.

The term pitch may refer to a distance between a center and a center. That is, in the present exemplary embodiment, a distance between a center and a center of the third pillar mask pattern P3 may be formed to be smaller than a distance between a center and a center of the first pillar mask pattern P1.

However, the important thing here is to keep the area ratio of the first pillar mask pattern P1 and the area ratio of the third pillar mask pattern P3 the same.

As described above, the pattern corresponds to an open region where a P-type impurity such as boron B can be implanted into the epitaxial layer, and it is possible to improve the charge imbalance even more clearly in all regions by keeping the pattern of the area occupied in the area of the unit cell constant.

Thus, as long as the area ratio of the first pillar mask pattern P1 and the area ratio of the third pillar mask pattern P3 remain the same, the shape of the first pillar mask pattern P1 and the shape of the third pillar mask pattern P3 may be changed in various ways, and the pitch of the first pillar mask and the pitch of the third pillar mask pattern P3 may also vary.

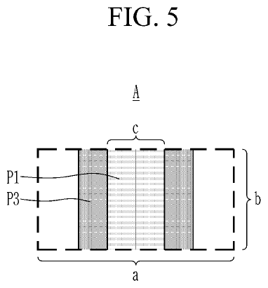

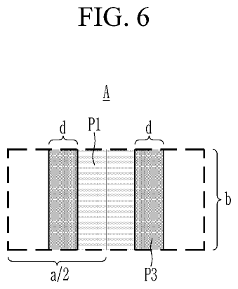

Referring to FIG. 5 and FIG. 6, each illustrates the unit cell marked by “A” in FIG. 4, and the area ratio of the first pillar mask pattern P1 and the area ratio of the third pillar mask pattern P3 can be calculated.

Referring to FIG. 5, the area of the unit cell is a×b, and the area of the first pillar mask pattern P1 is c×b, and thus the area ratio of the first pillar mask pattern P1 can be calculated as cb/ab. Here, a may correspond to the pitch of the unit cell of the first pillar mask pattern P1.

Next, referring to FIG. 6, the area of the unit cell is (a/2)×b, and the area of the third pillar mask pattern P3 is d×b, and thus the area ratio of the third pillar mask pattern P3 can be calculated as db/(ab/2). Here, (a/2) may correspond to the pitch of the unit cell of the third pillar mask pattern P3, and may be half the pitch of the unit cell of the first pillar mask pattern P1.

From this, in order for the area ratio of the first pillar mask pattern P1 and the area ratio of the third pillar mask pattern P3 to be the same, a conclusion that it is necessary to satisfy d=c/2 from db/(ab/2)=(cb)/(ab) can be obtained.

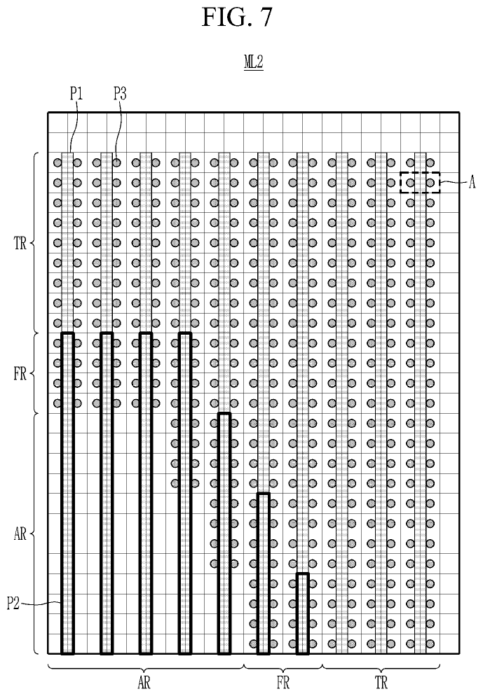

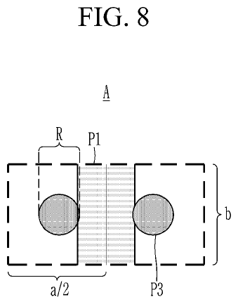

FIG. 7 and FIG. 8 are provided for description of an example of a mask layer for manufacturing a semiconductor device according to an exemplary embodiment of the present disclosure.

Referring to FIG. 7, unlike the exemplary embodiment of FIG. 4, in the mask layer ML2, a pattern of the third pillar mask pattern P3 for forming the upper frame region 125a connected to the second P-pillar 123, which is formed in the frame region FR, and the upper termination region 126a formed in the termination region TR to be connected to the upper frame region 125a, may have a circular shape.

In this case, the pitch of the third pillar mask pattern P3 of the surface of the termination region TR may be formed to be smaller than the pitch of the first pillar mask pattern P1. For example, the pitch of the third pillar mask pattern P3 of the surface of the termination region TR may be formed to be the half the pitch of the first pillar mask pattern P1.

As previously described with reference to FIG. 5 and FIG. 6, the charge imbalance can be more surely improved in all regions where the pillar is formed by keeping the area ratio of the area occupied in the unit cell area constant.

Referring to FIG. 8 illustrating the unit cell marked by “A” in FIG. 7, the area ratio of the first pillar mask pattern P1 and the area ratio of the third pillar mask pattern P3 can be calculated.

Referring to FIG. 8, the area of the unit cell is (a/2)×b and the area of the third pillar mask pattern P3 can be calculated as π*(R/2)². Accordingly, the area ratio of the third pillar mask pattern P3 can be calculated as {π*(R/2)²}/(ab/2).

From this, in order for the area ratio of the third pillar mask pattern P3 to be equal to the area ratio of the first pillar mask pattern P1, a conclusion that it is necessary to satisfy R=√(2cb/π) from {π*(R/2)2}/(ab/2)=(cb)/(ab), R=√(2cb/π) can be obtained.

Hereinafter, a method for manufacturing a semiconductor device 1 using, for example, a mask layer ML2 according to an exemplary embodiment of the present disclosure, will be described.

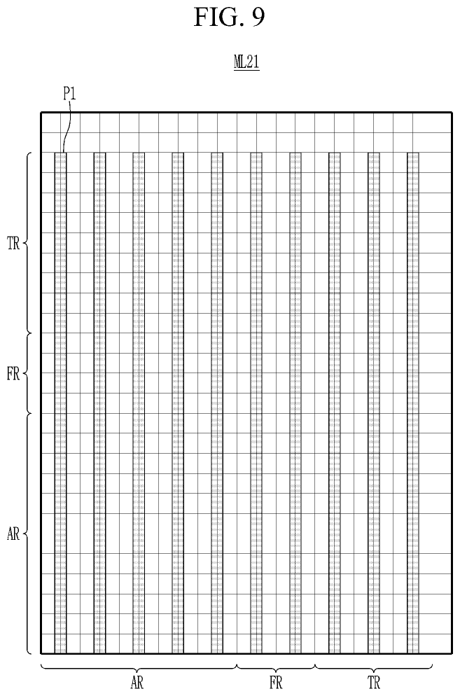

FIG. 9 to FIG. 15 are provided for description of an example of a method for manufacturing a semiconductor device by using the mask layer of FIG. 7.

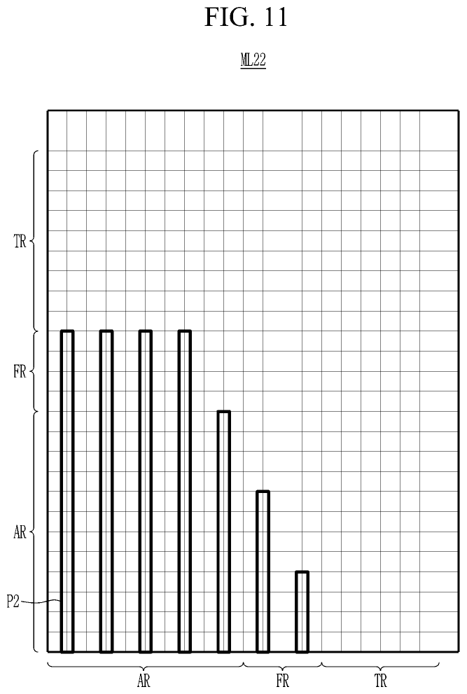

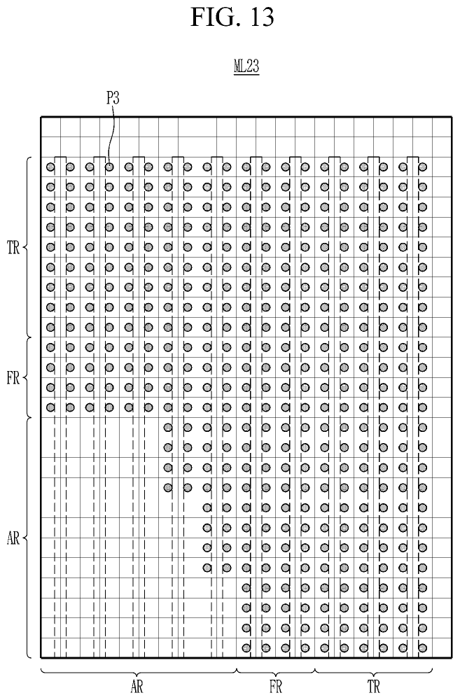

A mask layer ML21 shown in FIG. 9, a mask layer ML22 shown in FIG. 11, and a mask layer ML23 shown in FIG. 13 are implementation examples of the mask layer ML2 described with reference to FIG. 7. That is, a first P-pillar 121 may include only a first pillar mask P1 for forming an active region AR of the mask layer ML21, a second P-pillar 123 formed in the frame region FR, and a third P-pillar 127 formed in the termination region TR, the mask layer M22 may include only a second pillar mask pattern P2 for forming the first P-pillar 121 formed in the active region AR and the second P-pillar 123 formed in the frame region FR, and the mask layer ML23 may include only a third pillar mask pattern P3 for forming an upper frame region 125a connected with the second P-pillar 124 formed in the frame region FR and an upper termination region 126 formed in the termination region TR so as to be connected with the upper frame region 125a.

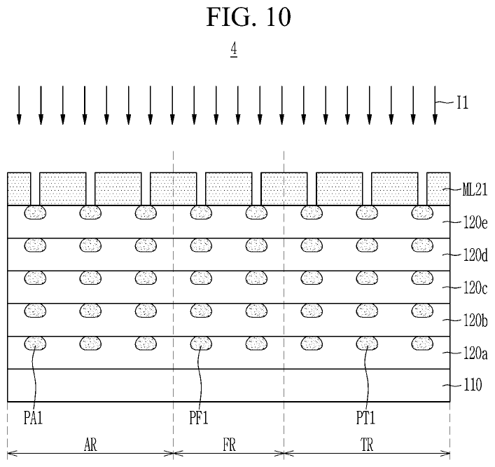

Referring to FIG. 9 and FIG. 10, a first epitaxial layer 120a may be formed on a first semiconductor layer 110 divided into the active region AR, the frame region FR, and the termination region TR, and the mask layer ML21 may be disposed on the first epitaxial layer 120a. Here, the first semiconductor layer 110 may be a part of a semiconductor substrate doped with an N-type impurity. Alternatively, the first semiconductor layer 110 may include a semiconductor layer doped with an N-type impurity and an epitaxial layer formed on the semiconductor substrate and doped with an N-type impurity.

The first epitaxial layer 120a may include an N-type impurity. For example, the first epitaxial layer 120a may be grown by being doped with an N-type impurity such as arsenic (As) or phosphorus (P).

In some exemplary embodiments of the present disclosure, the first epitaxial layer 120a may be formed by ion implantation of the N-type impurity into an epitaxial layer that is not doped or grown at low concentration, or, alternatively, the first epitaxial layer 120a may be formed by ion implantation of the N-type impurity only in a region where the N-pillar will be formed after patterning the region where the N-pillar is to be formed by using a mask on the epitaxial layer which is not doped or grown through low concentration doping, or may be formed in various other ways. In addition, the description is equally applicable to any epitaxial layer mentioned in this specification. The mask layer ML21 exposes a top surface that corresponds to an active region AR, a frame region FR, and a termination region TR of the first epitaxial layer 120a according to the shape shown in FIG. 9, and may implant a P-type impurity such as boron (B) with respect to a region not covered by the mask layer ML21 in the top surface of the first epitaxial layer 120a by performing an ion implantation process 11.

Accordingly, a preliminary active pillar layer PA1, a preliminary frame pillar layer PF1, and a preliminary termination pillar layer PT1 may be formed, respectively on upper sides of the active region AR, the frame region FR, and the termination region TR of the first epitaxial layer 120a. Next, the mask layer ML21 may be removed.

Next, a second epitaxial layer 120b is formed on the first epitaxial layer 120a where the preliminary active pillar layer PA1, the preliminary frame pillar layer PF1, and the preliminary termination pillar layer PT1 are formed, and then a preliminary active pillar layer PA1, a preliminary frame pillar layer PF1, and a preliminary termination pillar layer PT1 may be formed using the same method as described above on upper sides of the active region AR, the frame region FR, and the termination region TR of the second epitaxial layer 120b. Here, the second epitaxial layer 120b may have the same thickness as that of the first epitaxial layer 120a, but the range of the present disclosure is not limited thereto.

Such a process is repeated with respect to a third epitaxial layer 120c to a fifth epitaxial layer 120e such that a structure as shown in FIG. 10 can be acquired.

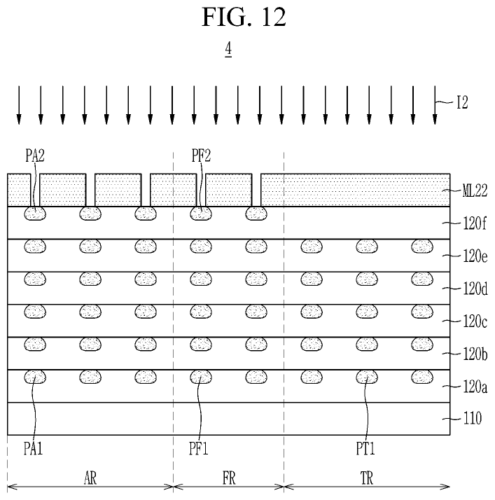

Next, referring to FIG. 11 and FIG. 12, a sixth epitaxial layer 120f may be formed on the fifth epitaxial layer 120e.

The mask layer ML22 exposes a top surface that corresponds to an active region AR and a frame region FR of the sixth epitaxial layer 120f according to the shape shown in FIG. 1, and performs an ion implantation process 12 such that a P-type impurity such as boron (B) can be implanted with respect to a region that is not covered by the mask layer ML22 in the top surface of the sixth epitaxial layer 120f.

Accordingly, a preliminary active pillar layer PA2 and a preliminary frame pillar layer PF2 may be respectively formed on upper sides of the active regions AR and the frame region FR of the sixth epitaxial layer 120f. Next, the mask layer ML22 can be removed.

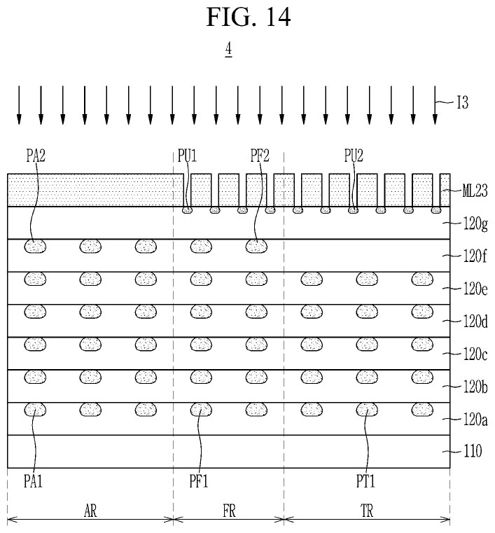

Next, referring to FIG. 13 and FIG. 14, a seventh epitaxial layer 120g may be formed on the sixth epitaxial layer 120f.

The mask layer ML23 exposes a top surface that corresponds to a frame region FR and a termination region TR of the seventh epitaxial layer 120g according to the shape shown in FIG. 13, and performs an ion implantation process 13 such that a P-type impurity such as boron (B) can be implanted with respect to a region that is not covered by the mask layer ML23 in the top surface of the seventh epitaxial layer 120g.

Accordingly, a preliminary upper frame region layer PU1 and a preliminary upper termination region layer PU2 may be respectively formed on upper sides of the frame region FR and the termination region TR of the seventh epitaxial layer 120g.

In some exemplary embodiments of the present disclosure, the preliminary upper frame region layer PU1 and the preliminary upper termination region layer PU2 may be smaller than the preliminary active pillar layer PA1, the preliminary frame pillar layer PF1, the preliminary termination pillar layer PT1, the preliminary active pillar layer PA2, and the preliminary frame pillar layer PF2 in size, that is, in width and height, but the range of the present disclosure is not limited thereto, and may be variously changed depending on an implementation purpose.

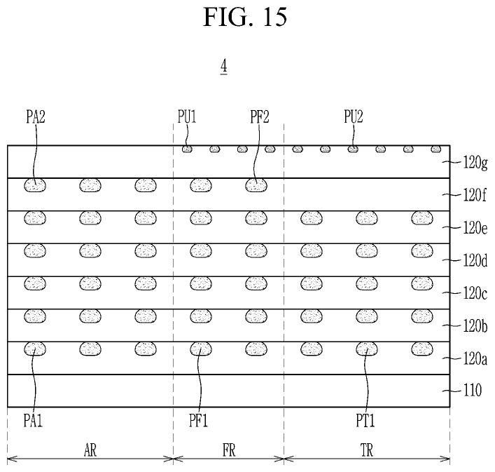

Next, referring to FIG. 15, the mask layer ML23 can be removed. Subsequently, an annealing process is performed on a structure formed up to the seventh epitaxial layer 120g such that impurities implanted into the preliminary active pillar layer PA1, the preliminary frame pillar layer PF1, the preliminary termination pillar layer PT1, the preliminary upper frame region layer PU1, and the preliminary upper termination region layer PU2 formed in the structure can be diffused by a predetermined distance in the horizontal direction and/or in the vertical direction.

Accordingly, in the active region AR, the preliminary active pillar layers PA1 of the first epitaxial layer 120a to the fifth epitaxial layer 120e and the preliminary active pillar layer PA2 of the sixth epitaxial layer 120f are connected with each other in the vertical direction such that a first P-pillar 121 that extends in a vertical direction can be formed. In addition, a portion disposed between two adjacent first P-pillars 121 may correspond to a first N-pillar 122.

Meanwhile, in the frame region FR, the preliminary frame pillar layers PF1 of the first epitaxial layer 120a to the fifth epitaxial layer 120e and the preliminary frame pillar layer PF2 of the sixth epitaxial layer 120f are connected with each other in the vertical direction such that a P-pillar 123 that extends in the vertical direction can be formed. In addition, a portion disposed between two adjacent second P-pillars 123 may correspond to a second N-pillar 124. Here, the corresponding region may form the above-described lower frame region 125b.

Further, the preliminary frame pillar layer PF2 of the sixth epitaxial layer 120f and the preliminary upper frame region layer PU1 of the seventh epitaxial layer 120g may be connected to each other to form the above-described upper frame region 125a.

Meanwhile, in the termination region TR, the preliminary frame pillar layers PF1 of the first epitaxial layer 120a to the fifth epitaxial layer 120e may be connected to each other in the vertical direction to form a third P-pillar 127 extending in the vertical direction. In addition, a portion disposed between two adjacent third P-pillars 127 may correspond to a third N-pillar 128. Here, the corresponding region may form the above-described lower termination region 126c.

In addition, the preliminary upper frame region layer PU1 of the seventh epitaxial layer 120g and the preliminary upper termination region layer PU2 are connected with each other to form an upper termination region 126a connected with the above-described upper frame region 125a in the first direction (X). Here, a region corresponding to the termination region TR in the sixth epitaxial layer 120f may correspond to the above-described middle termination region 126b.

Next, an additional ion implantation process may be performed to form a P body region 130, a P region 132, and an N region 134, an oxidation process to form a gate dielectric layer 136 and a field oxide layer 146, a deposit and patterning process to form an active poly gate 138 and a field plate 148, a deposit and patterning process to form a spacer 140 and an insulation layer 142, a deposit and patterning process to form a source electrode 144, a gate electrode 150, and a floating electrode 152, and the like are further performed before and after the ion implantation process, or between the ion implantation processes such that a super-junction semiconductor device can be manufactured.

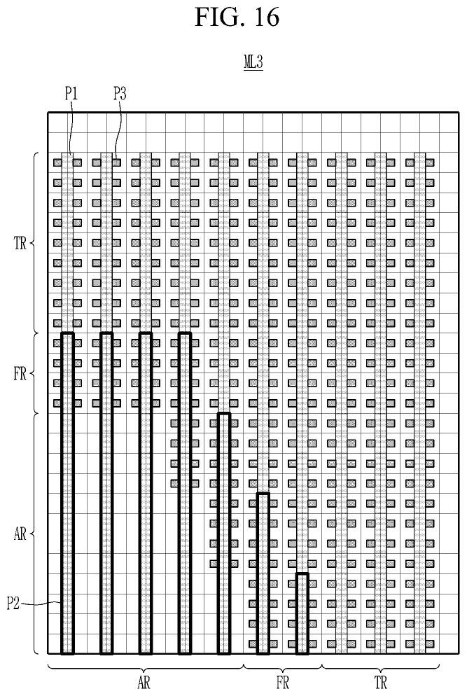

FIG. 16 is provided for description of another example of a mask layer for manufacturing a semiconductor device according to the exemplary embodiment of the present disclosure.

Referring to FIG. 16, a pattern shape of a third pillar mask pattern P3 of a mask layer ML3 may be a square. However, the range of the present disclosure is not limited thereto, and the pattern may have various shapes such as an oval, a quadrangle, a rectangle, a square, a rhombus, a triangle, a pentagon, a hexagon, and an octagon.

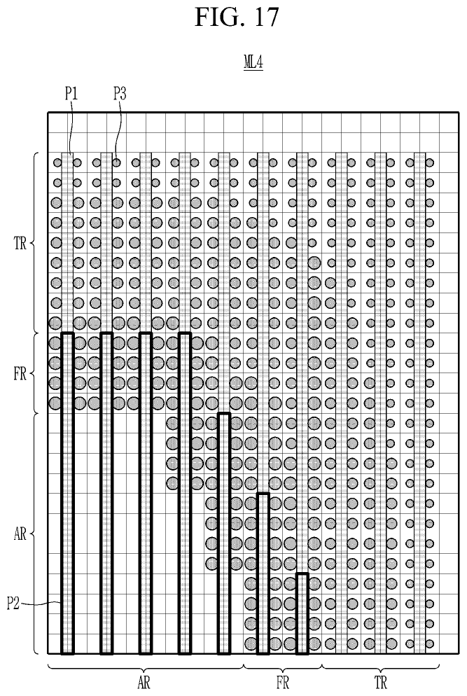

FIG. 17 is provided for description of another example of a mask layer for manufacturing a semiconductor device according to the exemplary embodiment of the present disclosure.

Referring to FIG. 17, a pattern of a third pillar mask pattern P3 of a mask layer ML4 has a circular shape, and the pitch of the third pillar mask pattern P3 may have various sizes according to positions. In the case of the mask layer ML4, the pitch of the third pillar mask pattern P3 is shown to decrease as the size of the circular shape decreases toward the outside of the termination region TR, but the range of the present disclosure is not limited thereto.

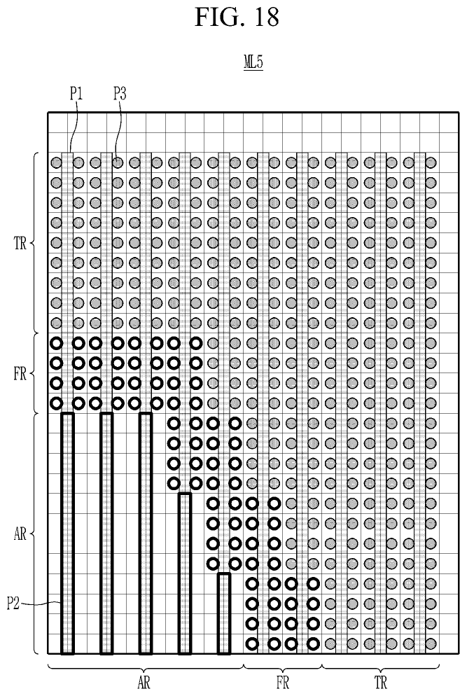

FIG. 18 is provided for description of another example of a mask layer for manufacturing a semiconductor device according to the exemplary embodiment of the present disclosure.

Referring to FIG. 18, a pattern of a frame region FR of a second pillar mask pattern P2 in a mask layer ML5 has a circular shape, and a pattern corresponds to an active region AR has a shape extending in one direction. However, the range of the present disclosure is not limited thereto, and may be variously modified according to a specific implementation purpose.

As described above with examples of the mask layers ML1 to ML5, the shape of the first pillar mask pattern P1 and the third pillar mask pattern P3 and the pitch of the first pillar mask pattern P1 and the pitch of the third pillar mask pattern P3 are variously adjusted to maintain the area ratio of the first pillar mask pattern P1 and the area ratio of the third pillar mask pattern P3 to be the same such that it is possible to refine the charge imbalance more precisely in all regions where the pillar is formed.

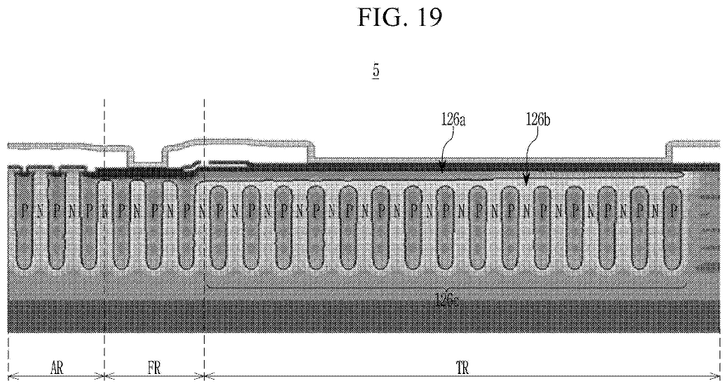

FIG. 19 is a cross-sectional view provided for description of a semiconductor device according to an exemplary embodiment of the present disclosure.

Referring to FIG. 19, a semiconductor device 5 according to an exemplary embodiment of the present disclosure may correspond to the semiconductor device 2 of FIG. 2A.

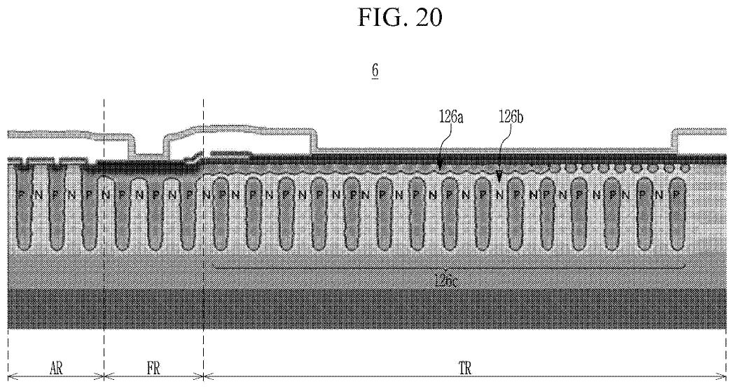

FIG. 20 is a cross-sectional view provided for description of a semiconductor device according to another exemplary embodiment of the present disclosure.

Referring to FIG. 20, a semiconductor device 6 according to an exemplary embodiment of the present disclosure may correspond to the semiconductor device 3 of FIG. 3.

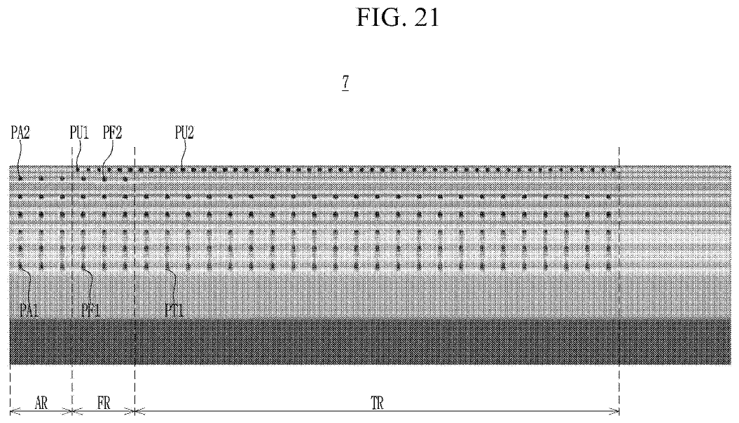

FIG. 21 is a cross-sectional view provided for description of a manufacturing step of a semiconductor device according to another exemplary embodiment of the present disclosure.

Referring to FIG. 21, a corresponding structure of a semiconductor device 7 according to an exemplary embodiment of the present disclosure may correspond to the structure described with reference to FIG. 15.

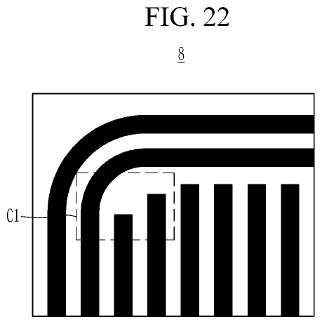

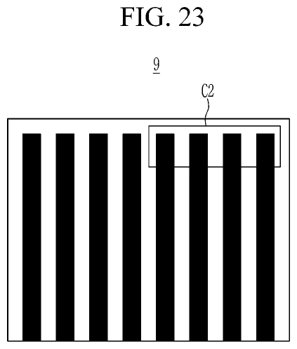

FIG. 22 and FIG. 23 are provided for description of advantageous effects of the semiconductor devices according to the exemplary embodiments of the present disclosure.

Referring to FIG. 22, when a pillar mask as a design shown in FIG. 22, a corner C1 may experience a charge imbalance problem and thus the P-type charge amounts and the N-type charge amount may not be balanced, and it is difficult to design a pillar mask for balancing charges in consideration of process dispersion.

Referring to FIG. 23, when the pillar mask has a design shown in FIG. 23, since a pillar shape in the horizontal direction and the vertical direction of the termination region is different, the depletion region expands quickly in the vertical direction and thus an end region C2 is vulnerable to a high electric field.

The largest influences on the expansion speed of the depletion region of the termination region or on the electric field applied to the termination region surface are the upper termination region corresponding to a type P, and the middle termination region corresponding to a type N. The larger the P-type charge of the upper termination region, the faster the expansion speed of the depletion region, and the larger the N-charge of the middle termination region, the slower the expansion speed of the depletion region. As a result, the peak of the electric field moves backward or forward.

Referring back to FIG. 2B and FIG. 2C, the upper termination region 126a and the middle termination region 126b of the semiconductor device of the exemplary embodiment according to the present disclosure are identically formed in upper, lower, left, and right sides of the drawing. Accordingly, it is possible to uniformize the expansion speed of the depletion region and distribution of electric fields over the entire region of the super-junction semiconductor device.

That is, a charge imbalance problem in which the balance between the P-type charge amount and the N-type charge amount is broken in a corner portion of the termination region of the super-junction semiconductor device can be solved according to the above-described variously exemplary embodiments of the present disclosure. In addition, the expansion speed of the depletion region can be adjusted to be uniform in all directions of the termination region surface to prevent damage from high electric fields, and the reliability of the super-junction semiconductor device can be secured and the performance can be improved by lowering the electric field level applied to the surface of the termination region and facilitating profile adjustment.

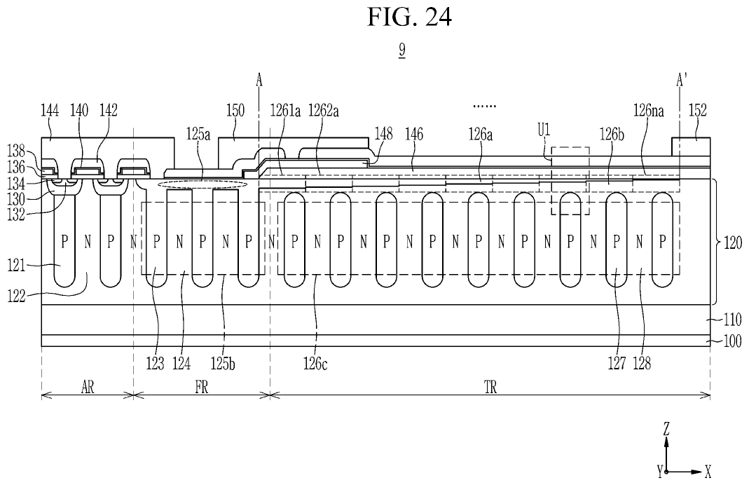

FIG. 24 is a cross-sectional view of one direction for description of a semiconductor device according to an exemplary embodiment of the present disclosure.

Referring to FIG. 24, a semiconductor device 9 according to an exemplary embodiment of the present disclosure may have a structure similar to that of the semiconductor device 2 in FIG. 2A. Accordingly, the description of the semiconductor device of FIG. 2 may be applied to the present embodiment as it is, to the extent that it does not correspond to the present embodiment.

The termination region TR of the second semiconductor layer 120 may include an upper termination region 126a, a middle termination region 126b, and a lower termination region 126c.

The upper termination region 126a may have a P-type of conductivity, and may extend in the first direction X that is parallel with the top surface of the first semiconductor layer 110. The impurity concentration of the upper termination region 126a may be designed to be non-uniform in the horizontal direction, i.e., the first direction X. The impurity concentration of the upper termination region 126a is highest on the left side and may decrease as it goes to the right side according to the first direction X.

Specifically, the upper termination region 126a may have a plurality of segmentation area 1261a to 126na, which can be logically defined to distinguish areas having different impurity concentrations in the upper termination region 126a. The impurity concentration of the first segmentation area 1261a may be the highest, the impurity concentration of the second segmentation area 1262a may be lower than that of the first segmentation area 1261a, the impurity concentration of the third segmentation area next to the second segmentation area 1262a in the first direction X may be lower than that of the second segmentation area 1262a, . . . , and the impurity concentration of the n-th segmentation area 126na may be the lowest. According to this structure, it is possible to implement a very stable electric field profile.

In some embodiments of present disclosure, the depth from the second semiconductor device 120 to the second direction Y, of the first segmentation area 1261a is the deepest, the depth of the second segmentation area 1262a may be shallower than that of the first segmentation area 1261a, the depth of the third segmentation area next to the second segmentation area 1262a in the first direction X may be shallower than that of the second segmentation area 1262a, . . . , and the depth of the n-th segmentation area 126na may be the shallowest.

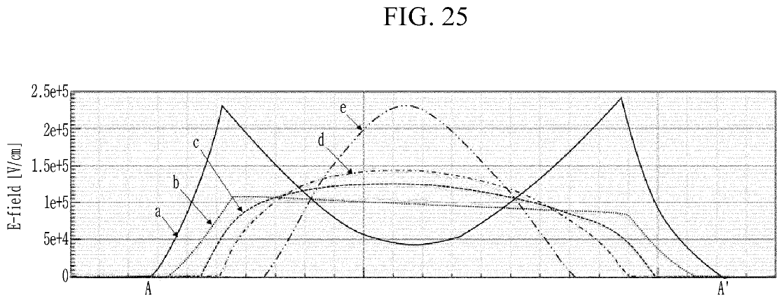

FIG. 25 illustrates a profile of a surface electric field along line AA′ of the semiconductor device of FIG. 24.

Referring to FIG. 25, the profile is a surface electric field profile under reverse bias condition between the drain and the source, along line AA′ of the semiconductor device 9. ‘a’, ‘b’, ‘c’, ‘d’, and ‘e’ refers to doping concentration change rates (i.e., doping concentration decrease rates) from the first segmentation area 1261a to the n-th segmentation area 126na according to the first direction X.

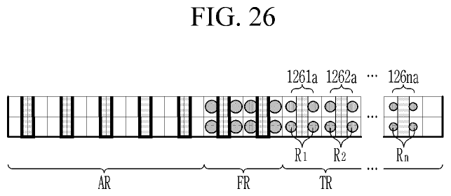

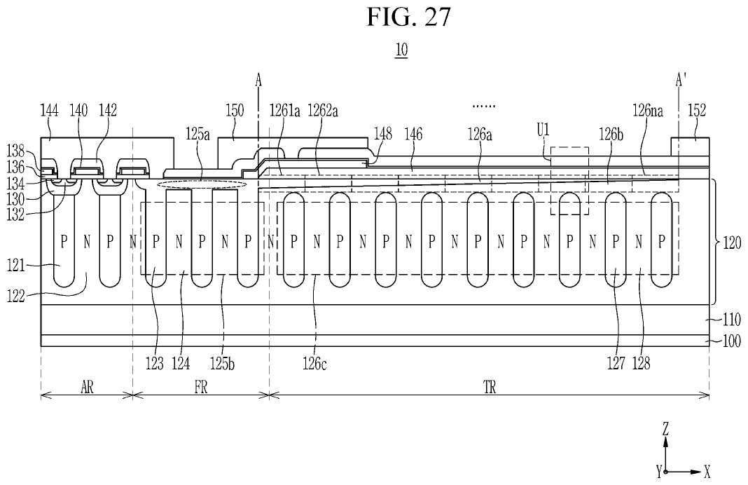

The cases of ‘a’ and ‘e’ are not preferable because the electric field peak value on the termination surface side is high, which may make operational characteristics of the semiconductor device unstable. Therefore, it is preferable that the doping concentration change rates be determined as in ‘b’, ‘c’, and ‘d’. To this end, an example method for adjusting the doping concentration will be described hereafter with reference to FIG. 26.

FIG. 26 is provided for description of an example of a mask layer for manufacturing the semiconductor device of FIG. 24.

Referring to FIG. 26, a part of the mask layer ML4 of FIG. 17 is described. A pattern of a third pillar mask pattern P3 of a mask layer ML4 has a circular shape, and a diameter of the third pillar mask pattern P3 is shown to decrease as the size of the circular shape decreases toward the outside of the termination region TR. In FIG. 26, R₁ is a diameter of the third pillar mask pattern P3 corresponding to first segmentation area 1261a, R₂ is a diameter of the third pillar mask pattern P3 corresponding to second segmentation area 1262a, and Rₙ is a diameter of the third pillar mask pattern P3 corresponding to second segmentation area 126na.

In some embodiments of present disclosure, it can be designed so that the diameter R₁, R₂, . . . , Rₙ decreases linearly by ΔR, as follows:

$$\begin{matrix}{R}_{1} - {R}_{2} = Δ R ; \\ {R}_{2} - {R}_{3} = Δ R ; \\ … \\ {R}_{n - 1} - {R}_{n} = Δ R .\end{matrix}$$

Herein, the decreasing step may be (R₁−R₂)/R₁×100(%).

In some embodiments of present disclosure, let A₁ be an area of the third pillar mask pattern P3 corresponding to first segmentation area 1261a, A₂ be an area of the third pillar mask pattern P3 corresponding to second segmentation area 1262a, and Aₙ be an area of the third pillar mask pattern P3 corresponding to second segmentation area 126na, and it can be designed so that the area A₁, A₂, . . . , Aₙ decreases linearly by ΔA, as follows:

$$\begin{matrix}{A}_{1} - {A}_{2} = Δ A ; \\ {A}_{2} - {A}_{3} = Δ A ; \\ … \\ {A}_{n - 1} - {A}_{n} = Δ A .\end{matrix}$$

Herein, the decreasing step may be (A₁−A₂)/A₁×100(%).

By adjusting the decreasing step in these way, it is possible to adjust the termination surface electric field profile. In particular, ‘a’, ‘b’, ‘c’, ‘d’, and ‘e’ of FIG. 25 indicate cases where the decreasing step is d %, 2d %, 3d %, 4d %, and 5d %, respectively. As a result, a stable electric field profile can be implemented by adjusting the decreasing step to be 2d %, 3d %, and 4d %.

While this disclosure has been described in connection with what is presently considered to be practical exemplary embodiments, it is to be understood that the disclosure is not limited to the disclosed embodiments. On the contrary, it is intended to cover various modifications and equivalent arrangements included within the spirit and scope of the appended claims.

What is claimed is:

1. A semiconductor device comprising:
a first semiconductor layer having an N-type of conductivity; and
a second semiconductor layer that is formed on the first semiconductor layer, and including an active region, a frame region, and a termination region,
wherein the active region comprises a plurality of first P-pillars and first N-pillars formed between the plurality of first P-pillars,
the frame region comprises an upper frame region formed to extend in a first direction while having a P-type of conductivity, and a lower frame region that is formed below the upper frame region and including a plurality of second P-pillars and second N-pillars formed between the plurality of second P-pillars, and
the termination region comprises an upper termination region that extends in the first direction while having the P-type of conductivity, a middle termination region having the N-type of conductivity and formed below the upper termination region, and a lower termination region formed below the middle termination region and including a plurality of third P-pillars and third N-pillars formed between the plurality of third P-pillars,
wherein the upper termination region comprises a plurality of segmentation area logically defined to distinguish areas having different impurity concentrations in the upper termination region, the plurality of segmentation area having a first segmentation area, a second segmentation area, and a third segmentation area, and
wherein the impurity concentration of the first segmentation area is the highest, the impurity concentration of the second segmentation area is lower than that of the first segmentation area, and the impurity concentration of the n-th segmentation area is the lowest.

2. The semiconductor device of claim 1, wherein the entire lower termination region is covered by the upper termination region.

3. The semiconductor device of claim 1, wherein the middle termination region and the upper termination region are sequentially formed on the third P-pillar.

4. The semiconductor device of claim 1, wherein the second P-pillar is connected to the top surface of the second semiconductor layer through the upper frame region.

5. The semiconductor device of claim 1, wherein the third P-pillar is distanced from the top surface of the second semiconductor layer.

6. The semiconductor device of claim 1, wherein the top surface of the middle termination region is distanced from the top surface of the second semiconductor layer.

7. The semiconductor device of claim 1, wherein the middle termination region is connected with at least one of the plurality of third N-pillars of the lower termination region.

8. The semiconductor device of claim 1, wherein the upper termination region is connected with the upper frame region.

9. The semiconductor device of claim 1, wherein the upper frame region is connected with at least one of the plurality of second P-pillars of the lower frame region.

10. The semiconductor device of claim 1, wherein impurity concentration of the upper frame region is higher than that of the upper termination region.
